(19) United States
(12) Patent Application Publication
(10) Pub. No.: US 2023/0402545 A1
(43) Pub. Date: Dec. 14, 2023

(54) UNIFORM SEMICONDUCTOR ACTIVE FIN WIDTH

(71) Applicant: International Business Machines Corporation, Armonk, NY (US)

(72) Inventors: Min Gyu Sung, Latham, NY (US); Ruilong Xie, Niskayuna, NY (US); Heng Wu, Santa Clara, CA (US); Julien Frougier, Albany, NY (US)

(21) Appl. No.: 17/837,150

(22) Filed: Jun. 10, 2022

(51) Int. Cl. H01L 29/78; H01L 29/10; H01L 29/66; H01L 27/088

(52) U.S. Cl. CPC H01L 29/7856; H01L 29/1037; H01L 29/66818; H01L 27/0886

(57) ABSTRACT

A semiconductor device and formation thereof. The semiconductor device includes a plurality of fins grouped in a fin array. A first profile of an upper portion of each of the plurality of fins in the fin array located above a top surface of a shallow trench isolation layer is substantially similar. A second profile of a bottom portion of one or more inner fins in the fin array located below the shallow trench isolation layer is different than a third profile of the bottom portion of edge fins in the fin array located below the shallow trench isolation layer. A width of the bottom portion of the edge fins in the fin array located below the shallow trench isolation layer is greater than a width of the bottom portion of the one or more inner fins in the fin array located below the shallow trench isolation layer.

### BACKGROUND OF THE INVENTION

The present invention relates generally to the field of semiconductors, and more particularly to semiconductor devices having uniform active fin widths.

A FinFET is a field effect transistor including a narrow, active area of a semicondcutor material protruding from a substrate so as to resemble a fin. The fin includes source and drain regions. Active areas of the fin are typically separated by shallow trench isolation (STI), such as SiO₂. The Fin FET also includes a gate region located between the source and the drain regions. The gate region is formed on a top surface and sidewalls of the fins so the gate region wraps around the fin. The portion of the fin extending under the gate between the source region and the drain region is the channel region.

One type of FinFET is fabricated on conventional bulk silicon wafers. Another type of FinFET is fabricated on silicon on insulator (SOI) wafers. A further evolution of the FinFET is a nanosheet FET (NS FET) or nanowire FET (NW FET) fabricated from alternating layers of vertically stacked semiconductor materials formed from an initial fin.

### SUMMARY

According to one embodiment of the present invention, a semiconductor device is provided. The semiconductor device includes a plurality of fins grouped in a fin array. A first profile of an upper portion of each of the plurality of fins in the fin array located above a top surface of a shallow trench isolation layer is substantially similar. A second profile of a bottom portion of one or more inner fins in the fin array located below the shallow trench isolation layer is different than a third profile of the bottom portion of edge fins in the fin array located below the shallow trench isolation layer. A width of the bottom portion of the edge fins in the fin array located below the shallow trench isolation layer is greater than a width of the bottom portion of the one or more inner fins in the fin array located below the shallow trench isolation layer.

According to another embodiment of the present invention, a method of forming a semiconductor device is disclosed. The method includes forming a fin array based, at least in part, on depositing a mask layer on a top surface of a substrate, and patterning the mask layer and the substrate to form a plurality of fins and a plurality of trenches located therebetween. The method further includes forming a shallow trench isolation layer, wherein an upper portion of the plurality of fins is located above a top surface of the shallow trench isolation layer and a bottom portion of the plurality of fins is located below the top surface of the shallow trench isolation layer. The method further includes forming a liner on exposed surfaces of the plurality of fins, the hard mask layer located on top of the plurality of fins, and the shallow trench isolation layer. The method further includes trimming the upper portion of the edge fins in the fin array located above the top surface of the shallow trench isolation layer.

### BRIEF DESCRIPTION OF THE SEVERAL VIEWS OF THE DRAWINGS

The following detailed description, given by way of example and not intend to limit the disclosure solely thereto, will best be appreciated in conjunction with the accompanying drawings, in which:

FIG. 1 illustrates a cross-sectional view depicting an initial set of semicondcutor fins of a semiconductor device, generally designated 100, in accordance with at least one embodiment of the present invention.

FIG. 2 illustrates a cross-sectional view of the structure depicted in FIG. 1 after subsequent processing steps, generally designated as semicondcutor device 200, in accordance with at least one embodiment of the present invention.

FIG. 3 illustrates a cross-sectional view of the structure depicted in FIG. 2 after subsequent processing steps, generally designated as semicondcutor device 300, in accordance with at least one embodiment of the present invention.

FIG. 4 illustrates a cross-sectional view of the structure depicted in FIG. 3 after subsequent processing steps, generally designated as semicondcutor device 400, in accordance with at least one embodiment of the present invention.

FIG. 5 illustrates a cross-sectional view of the structure depicted in FIG. 4 after subsequent processing steps, generally designated as semicondcutor device 500, in accordance with at least one embodiment of the present invention.

FIG. 6 illustrates a cross-sectional view of the structure depicted in FIG. 5 after subsequent processing steps, generally designated as semicondcutor device 600, in accordance with at least one embodiment of the present invention.

FIG. 7 illustrates a cross-sectional view of the structure depicted in FIG. 6 after subsequent processing steps, generally designated as semicondcutor device 700, in accordance with at least one embodiment of the present invention.

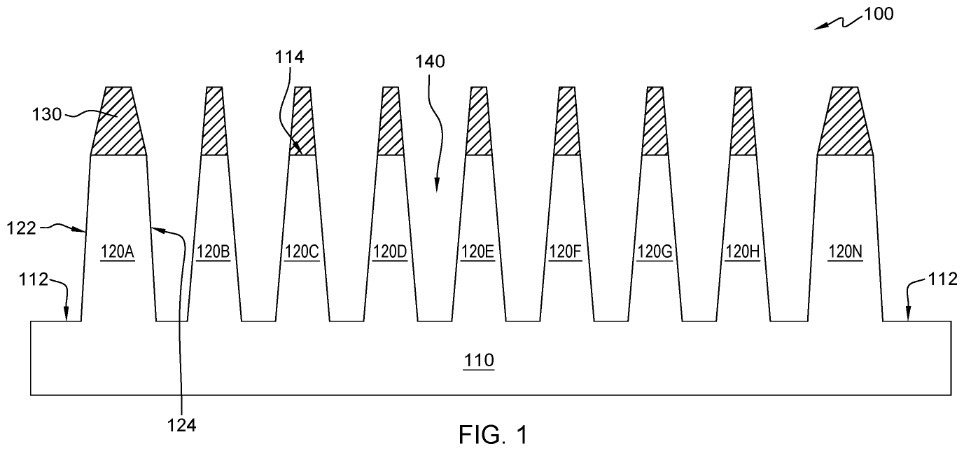

When viewed as ordered combinations, FIGS. 1-7 illustrate both (i) semiconductor devices having uniform active fin widths and (ii) the methods for forming such semiconductor devices having uniform active fin widths, in accordance with illustrative embodiments.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

The present invention relates generally to the field of semiconductors, and more particularly to semiconductor devices having uniform active fin widths.

Embodiments of the present invention recognize that uniformity in FinFET or nanosheet FET critical dimension (CD) width of the active areas of a fin/nanosheet array is crucial for maximizing semiconductor fin/nanosheet yields, as well as limiting unacceptable variations in electrical characteristics of semiconductor devices. However, as evinced by current lithography patterning limitations of FinFET or nanosheet FET arrays, the outermost fins/nanosheet stacks of the active region of a fin/nanosheet array are often formed having a larger CD width than that of the inner fins/nanosheet stacks of the array due to the loading effect induced by dry etching processes. This variation in CD width at the edges of the fin/nanosheet array results in unfavorable device variations in the electrical characteristics of the transistors formed in the active region. Should the variation in CD width be too large, the edge fins/nanosheet stacks can either be removed or left as dummy gates. However, either option leads to unfavorable results, such as decreasing fin/nanosheet yields and reducing transistor density.

Embodiments of the present invention provide for a semiconductor device, and methods for forming a semiconductor device having uniform and symmetrical FinFET/nanosheet FET profiles in the active region of the device. By forming uniform and symmetrical FinFETs/nanosheet FETs within the active device region, variations in electrical characteristics of transistors are reduced, while maximizing fin/nanosheet yields and increasing transistor density.

According to one embodiment of the present invention, a set of a predetermined number of fins are initially formed as a fin array on a substrate. For example, a mask layer is initially formed on the substrate and patterned to selectively remove portions of the substrate to form the initial set of fins. A shallow trench isolation (STI) layer is then formed within a portion of the trenches located between the set of fins such that an upper portion of the set of fins are located above a top surface of the STI layer and a bottom portion of the set of fins are located below the top surface of the STI layer. The device region located above the top surface of the STI layer forms the active region of the device. A liner is then formed on the exposed surfaces of the upper portion of the set of fins, the mask layer, and the top surface of the STI layer. Portions of the liner are then removed from the active device region to expose outer sidewall portions of the upper portions of the edge fins in the fin array. For example, an angled reactive ion etch (RIE) that is selective to the liner material over the materials of the fins and mask layer may be performed. The critical dimension (CD) width of the exposed sidewall portions of the edge fins located in the active device region are reduced (e.g., via isotropic trimming that is selective to the fins over the liner). The remaining liner and mask layer are then removed to produce a semiconductor device in which the upper portion of the fins in the fin array located within the active device region all have a uniform and symmetrical profile.

In an embodiment, the respective portions of the edge fins located above the top surface of the STI layer of the fin array have a line profile that is substantially similar and/or identical to a line profile of the respective portions of the inner fins located above the top surface of the STI layer. In other words, the CD width of the portions of the inner fins and the edge fins located in the active region of the semicondcutor device are substantially similar and/or identical. The CD width of the portions of the edge fins located below the top surface of the STI layer is wider than the CD width of the portions of the inner fins located below the top surface of the STI layer. In other words, the CD width of the portions of the edge fins located outside of or otherwise below the active device region is wider than CD width of the portions of the inner fins located outside of or otherwise below the active region of the semiconductor device. The line profile of the inner fins both above and below the top surface of the STI layer is symmetrical while the line profile of the edge fins is symmetrical above the top surface of the STI layer and asymmetrical below the top surface of the STI layer.

According to another embodiment of the present invention, a set of a predetermined number of nanosheet stacks are initially formed as a nanosheet array on a substrate. For example, a mask layer is initially formed on a single nanosheet stack and patterned to selectively remove portions of the initial nanosheet stack to form a nanosheet array. A shallow trench isolation (STI) layer is then formed within a portion of the trenches located between the nanosheet stacks such that an upper portion of the nanosheet stacks are located above a top surface of the STI layer and a bottom portion of the nanosheet stacks are located below the top surface of the STI layer. The device region located above the top surface of the STI layer forms the active region of the device. A liner is then formed on the exposed surfaces of the upper portion of the nanosheet stacks located above the top surface of the STI layer, the mask layer, and the top surface of the STI layer. Portions of the liner are then removed to expose outer sidewall portions of the edge nanosheet stacks of the nanosheet array. For example, an angled reactive ion etch (RIE) that is selective to the liner material layer over the materials of the nanosheet stacks and mask layer may be performed. The critical dimension (CD) width of the exposed sidewall portions of the edge nanosheet stacks of the nanosheet array are reduced (e.g., via isotropic trimming that is selective to the nanosheet stacks over the liner). The remaining liner and mask layer are then removed to produce a semiconductor device in which all of nanosheet stacks of the nanosheet array located in the active device region have a uniform and symmetrical profile.

In an embodiment, the respective portions of the edge nanosheet stacks located above the top surface of the STI layer of the nanosheet array have a line profile that is substantially similar and/or identical to a line profile of the respective portions of the inner nanosheet stacks located above the top surface of the STI layer. In other words, the CD width of the portions of the inner nanosheet stacks and the edge nanosheet stacks located in the active region of the semicondcutor device are substantially similar and/or identical. The CD width of the portions of the edge nanosheet stacks located below the top surface of the STI layer is wider than the CD width of the portions of the inner nanosheet stacks located below the top surface of the STI layer. In other words, the CD width of the portions of the edge nanosheet stacks located outside of the active region of the semicondcutor device is wider than CD width of the portions of the inner nanosheet stacks located outside the active region of the semiconductor device. The line profile of the inner nanosheet stacks both above and below the top surface of the STI layer is symmetrical while the line profile of the edge nanosheet stacks is symmetrical above the top surface of the STI layer and asymmetrical below the top surface of the STI layer.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

As described below, in conjunction with FIGS. 1-7, embodiments of the present invention include fin arrays and nanosheet arrays of a semicondcutor device having uniform and symmetrical profiles in the active device region, and methods of forming such semicondcutor device having uniform and symmetrical profiles in the active device region. The methods described below in conjunction with FIGS. 1-7 may be incorporated into typical semicondcutor manufacturing processes, such as fabrication processes. As such, when viewed as ordered combinations, FIGS. 1-7 illustrate methods for forming FinFET arrays and Nanosheet FET arrays having uniform and symmetrical fins/nanosheets in the active device region, thereby reducing electrical variations in the electrical characteristics of transistors, while maximizing fin/nanosheet yields and increasing transistor density.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

As used herein, terms such as “depositing,” “forming,” and the like may refer to the disposition of layers, or portions of materials, in accordance with a given embodiment. Such processes may or may not be different than those used in the standard practice of the art of microcooler device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, exposure to a specific frequency or range of frequencies of electromagnetic radiation, ion implantation techniques, and/or chemical/mechanical polishing (CMP). As used herein, terms, such as “forming,” and the like, may refer to processes that alter the structure of one or more layers of material, or portions of material(s), by removal of a quantity of material, in accordance with a given embodiment. For example, such formation processes may include, but are not limited to, micromachining, microetching, wet and/or dry etching processes, plasma etching processes, or any of the known etching processes in which material is removed.

Those skilled in the art understand that many different techniques may be used to add, remove, and/or alter various materials, and portions thereof, and that embodiments of the present invention may leverage combinations of such processes to produce the structures disclosed herein without deviating from the scope of the present invention.

The present invention will now be described in detail with reference to the Figures. FIGS. 1-7 include various cross-sectional views depicting illustrative steps of a method for manufacturing semicondcutor devices having uniform active fin widths and the resulting semicondcutor devices having uniform active fin widths according to select embodiments of the present invention. One having ordinary skill in the art will appreciate that there are many options available for the formation of the structures described herein and that the following discussion does not limit embodiments to only the techniques described herein.

It should be noted that for simplicity sake, the terms “semiconductor fins” or “fins” may be used interchangeably herein to describe both “fin-type” devices, such as FinFETs and “nanosheet-type” devices, such as NS FETs, unless indicated otherwise. In some embodiments, semiconductor fins 120A-120N are fins in a fin array that form a FinFET. In other embodiments, semiconductor fins 120A-120N are nanosheet stacks in a nanosheet array that form a nanosheet FET (NS FET).

As depicted, each of semiconductor fins 120A-120N extend perpendicularly from a top surface 112 of substrate 110. Substrate 110 may be part of a bulk semicondcutor substrate, or may be, for example, a layer in a silicon-on-insulator (SOI) substrate. In embodiments where substrate 110 is part of an SOI structure, substrate 110 may include a buried dielectric layer disposed on a silicon substrate. Substrate 110 can be made from any generally known semicondcutor materials, including, but not limited to, silicon, gallium arsenide, or germanium.

Each of semiconductor fins 120A-120N include a first sidewall portion 122 parallel to a second sidewall portion 124. In some embodiments, and as depicted, semiconductor fins 120A-120N are formed from the same material(s) as substrate 110. For example, both substrate 110 and semiconductor fins 120A-120N are made from silicon. In other embodiments, semiconductor fins 120A-120N are formed from a different material(s) than substrate 110. In an embodiment, substrate 110 is made from silicon and semiconductor fins 120A-120N are formed from an initial nanosheet structure that includes a stack of material layers with alternating layers of silicon (Si) and a sacrificial material (e.g., silicon germanium (SiGe) or germanium (Ge)), which is formed on substrate 110. In this embodiment, alternating layers of silicon and sacrificial material are formed on substrate 110 using an epitaxial growth process. Silicon layers of the initial nanosheet structure may be composed of undoped or doped silicon to form a channel for either (i) a nano-sheet n-channel field-effect transistor (n-FET) or (ii) a nano-sheet p-channel field-effect transistor (p-FET).

Semiconductor fins 120A-120N may be formed using any known material removal techniques. For example, mask layer 130 may initially be formed on substrate 110 or on an initial nanosheet stack (not depicted) formed on substrate 110. In an embodiment, mask layer 130 may include a resist or a hard mask patterned using resist (e.g., SiN, TiN, or other hard mask materials). In general, mask layer 130 is composed of any material or combination of materials that will act as a protecting layer for portions of substrate 110 or an initial nanosheet stack formed on substrate 110 during the formation of semicondcutor fins 120A-120N. Mask layer 130 may be patterned to expose underlying portions of substrate 110 or the initial nanosheet stack formed on substrate 110 while protecting other underlying portions of substrate 110 or the initial nanosheet stack formed on substrate 110. The exposed portions of substrate 110 or the initial nanosheet stack formed on substrate 110 are removed (e.g., wet, and/or dry etching) and the protected portions of substrate 110 or the initial nanosheet stack formed on substrate 110 are retained to form semiconductor fins 120A-120N having portions of the patterned mask layer 130 remaining on a top surface 114 thereof. The corresponding areas of substrate 110 or the initial nanosheet stack formed on substrate 110 removed to form semicondcutor fins 120A-120N also results in the formation of semiconductor trenches 140 between fins 120A-120N, respectively.

As depicted in FIG. 1, semicondcutor fins 120A-120N are shaped as trapezoidal-shaped fins. However, it should be appreciated that in other embodiments of the present invention, semiconductor fins 120A-120N can be formed having any known type of fin shape including, but not limited to, rectangular-shaped fins, pin-shaped fins, and diamond-shaped fins. Additionally, it should be appreciated that although semiconductor device 100 is depicted as having nine semicondcutor fins and eight semiconductor trenches, embodiments of the present invention may be practiced utilizing semiconductor devices having any number of fins and trenches therebetween.

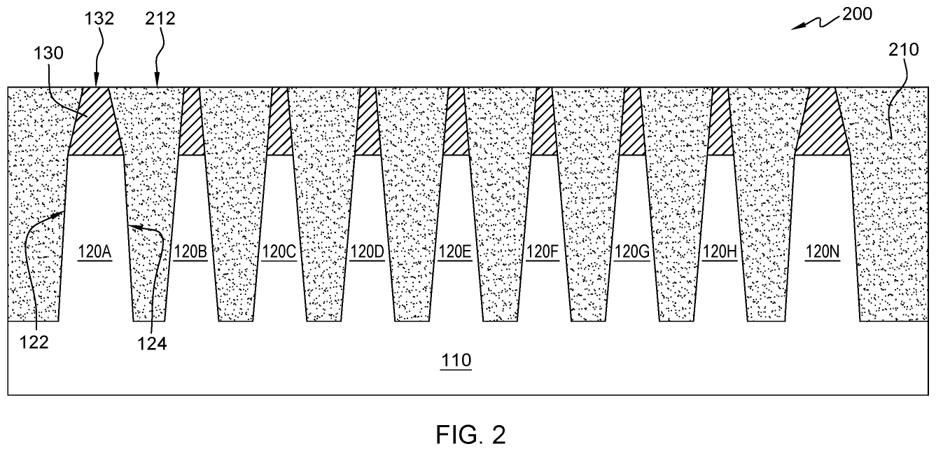

FIG. 2 illustrates a cross-sectional view of semiconductor device 100 depicted in FIG. 1 after subsequent processing steps, generally designated as semicondcutor device 200, in accordance with at least one embodiment of the present invention. As depicted by semiconductor device 200 of FIG. 2, a shallow trench isolation (STI) material layer 210 is formed (e.g., via atomic layer deposition, chemical vapor deposition, or any other suitable deposition techniques) over semiconductor device 200, including within semicondcutor trenches 140, to form isolation regions between semicondcutor fins 120A-120N. Specifically, STI material layer 210 is formed such that semicondcutor trenches 140 are filled with STI material layer 210 until a top surface 212 of STI material layer 210 is at least substantially coplanar with a top surface 132 of mask layer 130. As depicted in FIG. 2, STI material layer 210 is an insulation material, such as silicon dioxide (SiO₂). However, in other embodiments, STI material layer 210 can be formed from materials other than silicon dioxide, including, but not limited to, an oxide, such as silicon oxide (SiO), a nitride, an undoped polysilicon, or any combinations thereof.

In an embodiment, any excess STI material layer 210 formed above top surface 132 of mask layer 130 is removed (e.g., via chemical mechanical planarization (CMP) or “polishing,” or any other suitable material removal techniques) until top surface 132 of mask layer 130 is exposed and STI material layer 210 is substantially coplanar with top surface 132 of mask layer 130 as depicted in FIG. 2.

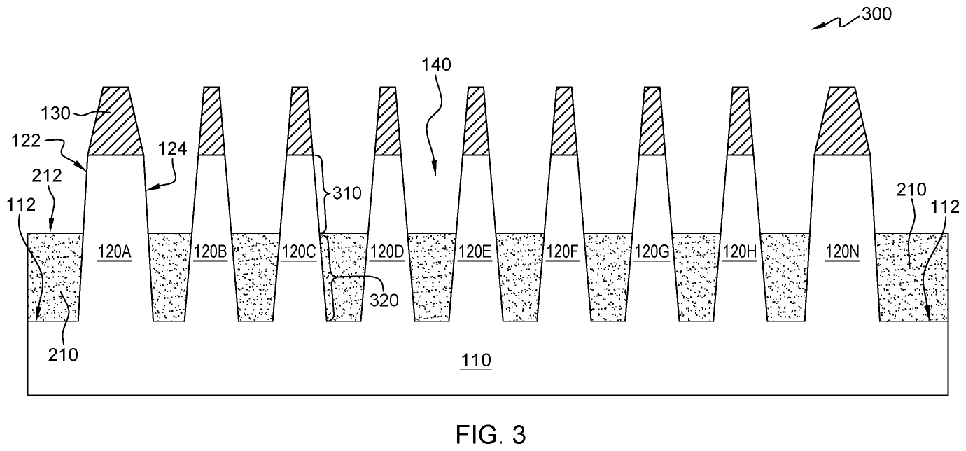

FIG. 3 illustrates a cross-sectional view of semiconductor device 200 depicted in FIG. 2 after subsequent processing steps, generally designated as semicondcutor device 300, in accordance with at least one embodiment of the present invention. As depicted by semicondcutor device 300 of FIG. 3, portions of STI material layer 210 formed within semicondcutor trenches 140, on top surface 112 of substrate 110 adjacent to first sidewall portion 122 of semiconductor fin 120A, and on top surface 112 of substrate 110 adjacent to second sidewall portion 124 of semiconductor fin 120N has been selectively removed (e.g., via a recess etch). In an embodiment, an etchant that is selective to STI material layer 210 over the materials of semicondcutor fins 120A-120N and mask layer 130 is applied to remove the portions of STI material layer 210 as depicted in FIG. 2. The depth of STI material layer 210 removed can be controlled using a timed etching process.

For example, if STI material layer is made from SiO₂, a wet chemical etchant for SiO₂ with a high selectivity over silicon is HF (49% in water). In an embodiment, some plasma etching processes for SiO₂ involve at least one of fluorine or carbon atoms. SF₆, NF₃, CF₄/O₂, and CF₄ are generally isotropic, but can be made more anisotropic with a higher involvement of ion species. Plasma etching of SiO₂ may be performed with the injection of a fluorocarbon gas into the processing chamber, where it is ionized and accelerated to the surface for etching. It should be appreciated that there are many etchants which are selective over Si and are anisotropic, including, but not limited to, CHF₃/O₂, C₂F₆, C₃F₈, and C₅F₈/CO/O₂/Ar. High ratios of fluorine atoms versus carbon atoms may be further considered when achieving a high selectivity of SiO₂ over Si.

After removal of the portions of STI material layer 210, an upper portion 310 of semiconductor fins 120A-120N is located above top surface 212 of STI material layer 210 and a lower portion 320 of semiconductor fins 120A-120N is located below top surface 212 of STI material layer 210. In other words, bottom portion 320 of semicondcutor fins 120A-120N remains covered by STI material layer 210 and upper portion 310 of semiconductor fins 120A-120N is uncovered as a result of removing the portions of STI material layer 210 as depicted in FIG. 2. Upper portion 310 of semiconductor fins 120A-120N form the active fin region or active device region for a transistor to be formed.

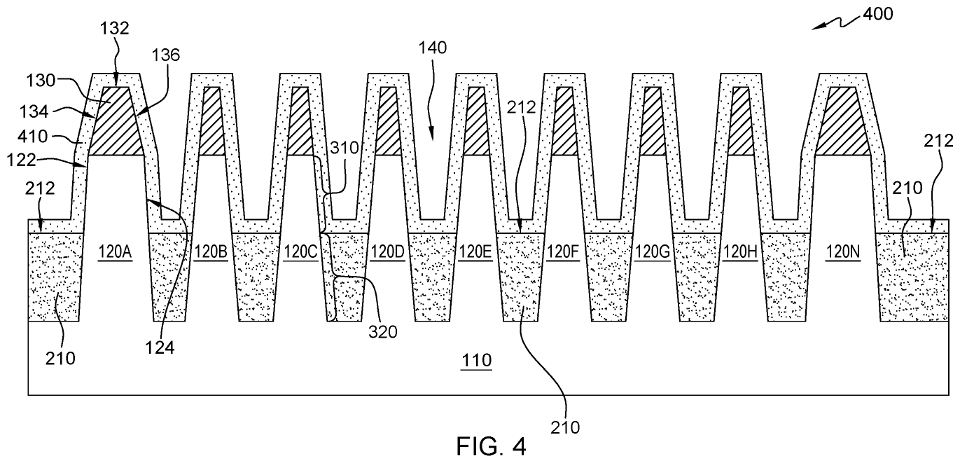

FIG. 4 illustrates a cross-sectional view of semicondcutor device 300 depicted in FIG. 3 after performing subsequent processing steps, generally designated as semiconductor device 400, in accordance with at least one embodiment of the present invention. As depicted by semiconductor device 400 of FIG. 4, an oxide liner 410 is formed on the exposed surfaces of semicondcutor device 400, including on top surface 212 of STI material layer 210 formed within semiconductor trenches 140, adjacent to first sidewall portion 122 of upper portion 310 of semiconductor fin 120A, adjacent to second sidewall portion 124 of upper portion 310 of semiconductor fin 120N, on first sidewall portion 122 of upper portion 310 of each of semiconductor fins 120A-120N, on second sidewall portion 124 of upper portion 310 of each of semicondcutor fins 120A-120N, and on top surface 132, first sidewall portions 134, and second sidewall portions 136 of mask layer 130, respectively. Oxide liner 410 may include one or more thin layers of material such as, for example, silicon oxide or silicon dioxide. A conformal layer of oxide liner 410 may be deposited using known techniques including, but not limited to, chemical vapor deposition (CVD), plasma enhanced chemical vapor deposition (PECVD), atomic layer deposition (ALD), physical vapor deposition (PVD), sputtering, and chemical solution deposition. The thickness of oxide liner 410 may vary depending on the deposition process used, as well as the material employed. In some embodiments, oxide liner 410 may have a thickness from 2 nm to nm. However, embodiments of the present invention are not limited to this range in the thickness of oxide liner 410.

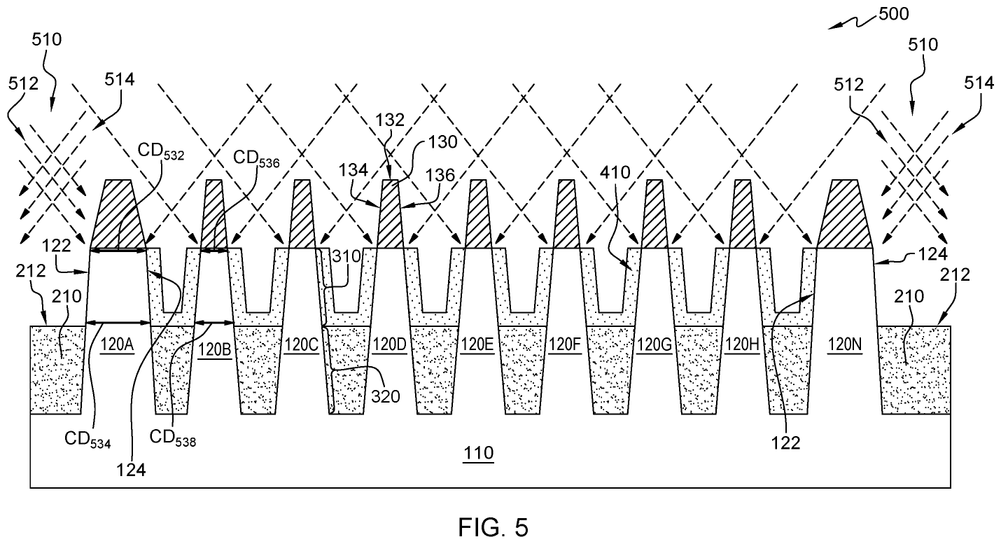

FIG. 5 illustrates a cross-sectional view of semicondcutor device 400 depicted in FIG. 4 after performing subsequent processing steps, generally designated as semiconductor device 500, in accordance with at least one embodiment of the present invention. As depicted by semicondcutor device 500 of FIG. 5, portions of oxide liner 410 formed on semiconductor device 400 have been removed. Specifically, oxide liner 410 has been removed from top surface 132, first sidewall portions 134, and second sidewall portions 136 of mask layer 130, first sidewall portion 122 of upper portion 310 of semiconductor fin 120A, second sidewall portion 124 of upper portion 310 of semiconductor fin 120N, top surface 212 of STI material layer 210 adjacent to first sidewall portion 122 of upper portion 310 of semicondcutor fin 120A, and top surface 212 of STI material layer 210 adjacent to second sidewall portion 124 of upper portion 310 of semicondcutor fin 120N. In an embodiment, dry etch techniques (e.g., an anisotropic etch process, such as reactive ion etch (RIE) or angled RIE) may be employed to selectively remove the previously listed portions of oxide liner 410 as depicted in FIG. 5. It should be noted that any type of etchant that is selective to the material of oxide liner 410 over the materials of mask layer 130 (e.g., silicon nitride (SiN)) and the material(s) of semiconductor fins 120A-120N (e.g., silicon in the case of a FinFET or alternating layers of silicon and silicon germanium in the case of a NS FET) can be used.

In an embodiment in which angled RIE is used, angled ions 510 may be provided in a reactive ion etching mixture, wherein the angled ions 510 selectively etch portions of oxide liner 410 over mask layer 130 and semicondcutor fins 120A-120N. Such reactive ion etching mixture may employ any suitable combination of gas phase species known in the art for selectively etching oxide liner 410 over mask layer 130 and semiconductor fins 120A-120N. For example, if oxide liner 410 is formed from silicon oxide, a reactive ion etching mixture may be selected that etches silicon oxide and not silicon, the material of semiconductor fins 120A-120N and silicon nitride, the material of mask layer 130.

Angled ions 510 may be provided as an ion beam by any known reactive angled ion beam etching devices. Reactive angled ion beam etching may direct ions in a reactive ion etching environment at a controlled, non-zero angle of incidence with respect to a perpendicular to a substrate plane. This geometry facilitates directing ions to select portions of substrate structures for instance. The trajectories of angled ions 510 may be mutually parallel to one another or may lie within a narrow angular range, such as within 10 degrees of one another or less. In some embodiments, angled ions 510 may be directed in a first direction 512 towards oxide liner 410 and a second direction 514 towards oxide liner 410 by rotating semiconductor device 180 degrees. In other words, a first portion of oxide liner 410 may be subject to a first exposure to angled ions 512 when semicondcutor device 500 is in a first rotational position and a second portion of oxide liner 410 may be subject to a second exposure to angled ions 514 when semicondcutor device 500 is in a second rotational position that is 180 degrees different than the first rotational position. In other embodiments, angled ions 510 may be simultaneously directed in multiple directions.

It should be appreciated that due to the presence of mask layer 130 formed on top surface 114 of semiconductor fins 120A-120N and the angle at which angled ions 510 are directed towards semiconductor device 500, second sidewall portion 124 of upper portion 310 of semiconductor fins 120A-H and first sidewall portion 122 of upper portion 310 of semicondcutor fins 120B-120N remain covered by oxide liner 410 after the angled RIE process. On the other hand, first sidewall portion 122 of upper portion 310 of semiconductor fin 120A and second sidewall portion 124 of upper portion 310 of semicondcutor fin 120N are now uncovered after the angled RIE process. In other words, oxide liner 410 is removed from the outermost sidewalls of the portions of the outermost semiconductor fins (120A and 120N) located above top surface 212 of STI material layer 210.

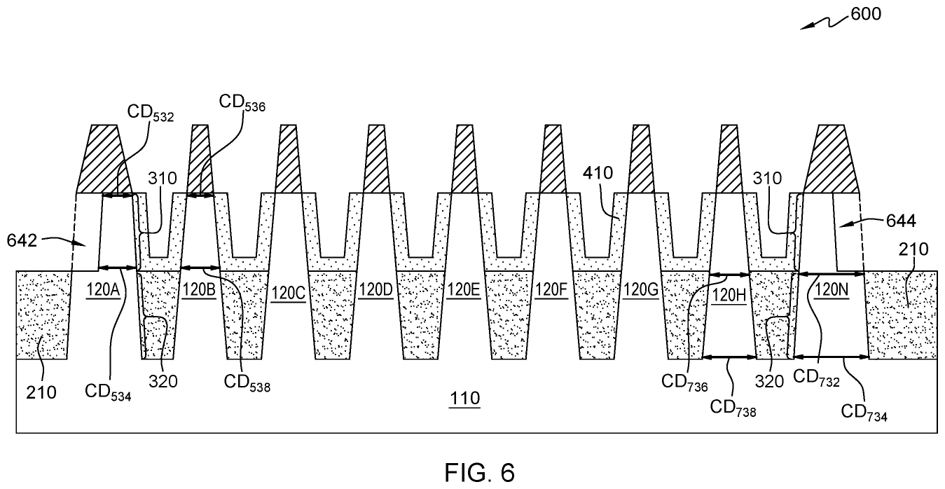

FIG. 6 illustrates a cross-sectional view of semiconductor device 500 depicted in FIG. 5 after performing subsequent processing steps, generally designated as semicondcutor device 600, in accordance with at least one embodiment of the present invention. As depicted by semiconductor device 600 of FIG. 6, a first target area 642 of upper portion 310 of semiconductor fin 120A and a second target area 644 of upper portion 310 of semiconductor fin 120N have been selectively trimmed (e.g., via wet and/or dry etching) to match the CD width(s) of upper portions 310 of semiconductors 120B-120H.

Turning now to semiconductor device 500 of FIG. 5, prior to selectively trimming first target area 642 of semiconductor fin 120A and second target area 644 of semiconductor fin 120N, upper portions 310 of semiconductor fins 120A and 120N had a first critical dimension CD₅₃₂ (i.e., a smallest lateral width) and a second critical dimension CD₅₃₄ (i.e., a largest lateral width). Similarly, upper portions 310 of semiconductor fins 120B-120H had a first critical dimension CD₅₃₆ (i.e., a smallest lateral width) and a second critical dimension CD₅₃₈ (i.e., a largest lateral width). As further depicted in FIG. 5, first critical dimension CD₅₃₂ of upper portions 310 of semiconductor fins 120A and 120N is larger than first critical dimension CD₅₃₆ of upper portions 310 of semiconductor fins 120B-120H. Similarly, second critical dimension CD₅₃₄ of upper portions 310 of semiconductor fins 120A and 120N is larger than second critical dimension CD₅₃₈ of semiconductor fins 120B-120H.

Returning back to semiconductor device 600 of FIG. 6, after selectively trimming first target area 642 of upper portion 310 of semiconductor fin 120A and second target area 644 of upper portion 310 of semiconductor fin 120N, first critical dimension CD₅₃₂ (i.e., a smallest lateral width) and a second critical dimension CD₅₃₄ (i.e., a largest lateral width) of upper portions 310 of semiconductor fins 120A and 120N have been reduced, while first critical dimension CD₅₃₆ (i.e., a smallest lateral width) and second critical dimension CD₅₃₈ (i.e., a largest lateral width) of semiconductor fins 120B-120H remain the same. As further depicted in FIG. 6, first critical dimension CD₅₃₂ of upper portions 310 of semiconductor fins 120A and 120N is now substantially similar and/or identical to first critical dimension CD₅₃₆ of upper portions 310 of semiconductor fins 120B-120H. Similarly, second critical dimension CD₅₃₄ of upper portions 310 of semiconductor fins 120A and 120N is now substantially similar and/or identical to second critical dimension CD₅₃₈ of semiconductor fins 120B-120H. In other words, a smallest lateral width of the upper portion of the edge fins in the fin array located above the shallow trench isolation layer is substantially similar to a smallest lateral width of the upper portion of the one or more inner fins in the fin array located above the shallow trench isolation layer. Similarly, a largest lateral width of the upper portion of the edge fins in the fin array located above the shallow trench isolation layer is substantially similar to a largest lateral width of the upper portion of the one or more inner fins in the fin array located above the shallow trench isolation layer.

As further depicted in FIG. 6, a third critical dimension CD₇₃₂ (i.e., a smallest lateral width) of bottom portions 320 of the edge semiconductor fins 120A and 120N is greater than a third critical dimension CD₇₃₆ (i.e., a smallest later width) of bottom portions 320 of the inner semiconductor fins 120B-120H. Similarly, a fourth critical dimension CD₇₃₄ (i.e., a greatest later width) of bottom portions 320 of the edge semiconductor fins 120A and 120N is greater than a fourth critical dimension CD₇₃₈ (i.e., a greatest lateral width) of bottom portions 320 of the inner semiconductor fins 120B-120H. In other words, a smallest lateral width of the bottom portions of the edge fins in the fin array located below the shallow trench isolation layer is greater than a smallest lateral width of the bottom portions of the one or more inner fins in the fin array located below the shallow trench isolation layer. Similarly, a largest lateral width of the bottom portions of the edge fins in the fin array located below the shallow trench isolation layer is greater than a largest lateral width of the bottom portions of the one or more inner fins in the fin array located below the shallow trench isolation layer.

In an embodiment, an etchant that is selective to the material of semicondcutor fins 120A and 120N over the material of oxide liner 410 is applied to reduce the smallest lateral width and largest lateral width of upper portions of semiconductor fins 120A and 120 N to match that of upper portions 310 of semiconductor fins 120B-120H. In an embodiment, an isotropic plasma etching process is performed to selectively remove targeted portions 642 and 644 of semiconductor fins 120A and 120N over STI material layer 210 and oxide layer 410. In an embodiment, an oxidation/oxide strip process is performed in which the exposed sidewall portions of semicondcutor fins 120A and 120N are oxidized (e.g., using a thermal oxidation process) and the oxide stripped to trim semicondcutor fins 120A and 120N as depicted in FIG. 6. This oxidation/oxide strip process can be repeated multiple times until a desired fin CD width(s) of upper portions 310 of semiconductor fins 120A and 120N located above STI material layer 210 is achieved. However, it should be appreciated that any known isotropic etching processes that are selective to the material of semiconductor fins 120A and 120N and that apply equal etch rates for all spatial directions may be used to remove targeted portions 642 and 644 of upper portions 310 of semiconductors 120A and 120N, respectively. The etch rate of isotropic etching processes can be controlled, for example, by transport processes with directional-independent transport rate or by using a timed etching process.

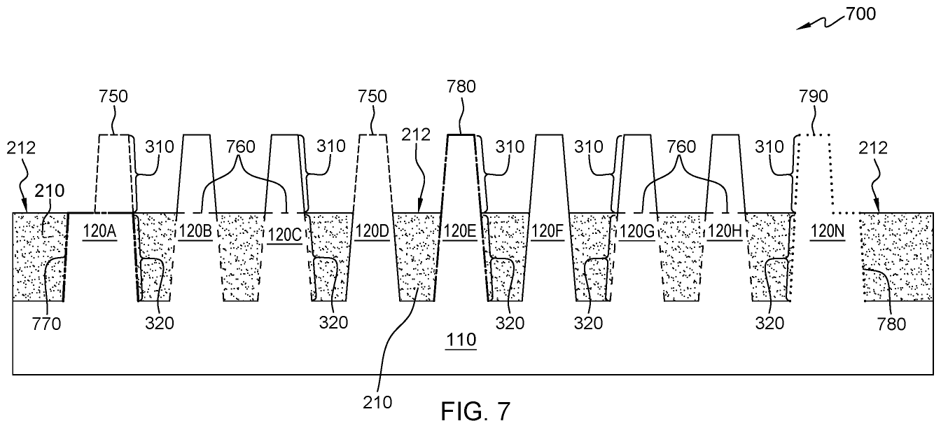

FIG. 7 illustrates a cross-sectional view of semicondcutor device 600 depicted in FIG. 6 after performing subsequent processing steps, generally designated 700, in accordance with at least one embodiment of the present invention. As depicted by semicondcutor device 700 of FIG. 7, mask layer 130 and oxide liner 410 have been removed. Mask layer 130 can be removed utilizing one or more material removal processes. For example, mask layer 130 can be removed utilizing a planarization process such as, for example, chemical mechanical polishing and/or grinding. Oxide liner 410 can be removed utilizing one or more material removal processes that are selective to the material of oxide liner 410.

As further depicted by FIG. 7, linear tapered profiles 750 of upper portions 310 of the edge semiconductor fins 120A and 120N are substantially similar and/or identical to linear tapered profiles 750 of upper portions 310 of the inner semiconductor fins 120B-120H. In other words, the line profile of each of semiconductor fins 120A-120N located above top surface 212 of STI material layer 210 is substantially similar and/or identical to one another. As further depicted, linear tapered profiles 750 of upper portions 310 of semiconductor fins 120A-120N are symmetrical.

Bottom portions 320 of each of the inner semiconductor fins 120B-120H have linear tapered profiles 760 that are symmetrical and substantially similar and/or identical to one another. Bottom portions 320 of the edge semiconductor fins 120A and 120N also have linear tapered profiles 770. However, linear tapered profiles 770 of bottom portions 320 of the edge semiconductor fins 120A and 120N have a wider profile than linear tapered profiles 770 of bottom portions 320 of the inner semiconductor fins 120B-120H.

As further depicted by FIG. 7, the combined upper portions 310 and bottom portions 320 of inner semiconductor fins 120B-120H form a symmetrical profile (e.g., a symmetrical linear tapered profile). The combined upper portions 310 and bottom portions 320 of edge semiconductor fins 120A and 120N form an asymmetrical profile 790 that is distinct from profile 780 of the inner semiconductor fins 120B-120H.

It should be appreciated that embodiments of the present invention are not limited to upper portions 310 and lower portions 320 of semicondcutor fins 120A-120N having a linear tapered profile. For example, in alternative embodiments, the profiles of semiconductor fins 120A-120N may have a parabolic tapered profile, an exponential tapered profile, or non-tapered profile (e.g., a continuous width from top to bottom).

According to one embodiment of the present invention, a method of forming a semicondcutor device is provided, the method comprising: forming a fin array based, at least in part, on depositing a mask layer on a top surface of a substrate and patterning the mask layer and the substrate to form a plurality of fins and a plurality of trenches located therebetween; forming a shallow trench isolation layer, wherein an upper portion of the plurality of fins is located above a top surface of the shallow trench isolation layer and a bottom portion of the plurality of fins is located below the top surface of the shallow trench isolation layer; forming a liner on exposed surfaces of the plurality of fins, the hard mask layer located on top of the plurality of fins, and the shallow trench isolation layer; and trimming the upper portion of the edge fins in the fin array located above the top surface of the shallow trench isolation layer.

In an embodiment, forming the shallow trench isolation layer further includes depositing a shallow trench isolation material within the plurality of trenches and on the top surface of the substrate adjacent to the edge fins in the fin array, and recessing a portion of the shallow trench isolation material to expose the upper portion of the plurality of fins located above the top surface of the shallow trench isolation layer.

In an embodiment, trimming the upper portion of the edge fins further includes removing respective portions of an exposed outer sidewall of the edge fins in the fin array located above the shallow trench isolation layer via an angled reactive ion etch that is selective to the plurality of fins over the shallow trench isolation layer and the liner.

In an embodiment, the angled reactive ion etch is terminated when a smallest lateral width of the upper portion of the edge fins in the fin array located above the shallow trench isolation layer is substantially similar to a smallest lateral width of the upper portion of the one or more inner fins in the fin array located above the shallow trench isolation layer, and a largest lateral width of the upper portion of the edge fins in the fin array located above the shallow trench isolation layer is substantially similar to a largest lateral width of the upper portion of the one or more inner fins in the fin array located above the shallow trench isolation layer.

In an embodiment, the method of forming the semiconductor device further includes, responsive to trimming the upper portion of the edge fins in the fin array located above the top surface of the shallow trench isolation layer, removing the mask layer and the liner from the semiconductor device.

In an embodiment, the plurality of fins in the fin array are formed from at least one of silicon, gallium arsenide, germanium, or a nanosheet stack.

In an embodiment, the shallow trench isolation layer is formed from at least one material selected from the group consisting of silicon dioxide (SiO₂), silicon oxide (SiO), a nitride, an undoped polysilicon, and combinations thereof.

In an embodiment, fin array is formed as part of a FinFET or a Nanosheet FET.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein.

In addition, any specified material or any specified dimension of any structure described herein is by way of example only. Furthermore, as will be understood by those skilled in the art, the structures described herein may be made or used in the same way regardless of their position and orientation. Accordingly, it is to be understood that terms and phrases such as, for instance, “side”, “over”, “perpendicular”, “tilted”, etc., as used herein refer to relative location and orientation of various portions of the structures with respect to one another, and are not intended to suggest that any particular absolute orientation with respect to external objects is necessary or required.

The foregoing specification also describes processing steps. While some of the steps may be in an ordered sequence, others may in different embodiments from the order that they were detailed in the foregoing specification. The ordering of steps when it occurs is explicitly expressed, for instance, by such adjectives as, “ordered”, “before”, “after”, “following”, and others with similar meaning.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art.

What is claimed is:

1. A semiconductor device, comprising:
a plurality of fins grouped in a fin array, wherein:
a first profile of an upper portion of each of the plurality of fins located above a top surface of a shallow trench isolation layer is substantially similar;
a second profile of a bottom portion of one or more inner fins in the fin array located below the shallow trench isolation layer is different than a third profile of the bottom portion of edge fins in the fin array located below the shallow trench isolation layer; and
a width of the bottom portion of the edge fins in the fin array located below the shallow trench isolation layer is greater than a width of the bottom portion of the one or more inner fins in the fin array located below the shallow trench isolation layer.

2. The semiconductor device of claim 1, wherein the first profile of the upper portion of each of the plurality of fins located above the top surface of the shallow trench isolation layer is at least one type of profile selected from the group consisting of a linear tapered profile, a parabolic tapered profile, an exponential tapered profile, and a non-tapered profile having a constant width.

3. The semiconductor device of claim 1, wherein the one or more inner fins in the fin array have at least one type of profile selected from the group consisting of a linear tapered profile, a parabolic tapered profile, an exponential tapered profile, and a non-tapered profile having a constant width.

4. The semiconductor device of claim 1, wherein the one or more inner fins in the fin array have a symmetrical profile and the edge fins in the fin array have an asymmetrical profile.

5. The semiconductor device of claim 1, wherein:
a smallest lateral width of the upper portion of the edge fins in the fin array located above the shallow trench isolation layer is substantially similar to a smallest lateral width of the upper portion of the one or more inner fins in the fin array located above the shallow trench isolation layer; and
a largest lateral width of the upper portion of the edge fins in the fin array located above the shallow trench isolation layer is substantially similar to a largest lateral width of the upper portion of the one or more inner fins in the fin array located above the shallow trench isolation layer.

6. The semiconductor device of claim 1, wherein:
a smallest lateral width of the bottom portion of the edge fins in the fin array located below the shallow trench isolation layer is greater than a smallest lateral width of the bottom portion of the one or more inner fins in the fin array located below the shallow trench isolation layer; and
a largest lateral width of the bottom portion of the edge fins in the fin array located below the shallow trench isolation layer is greater than a largest lateral width of the bottom portion of the one or more inner fins in the fin array located below the shallow trench isolation layer.

7. The semiconductor device of claim 1, wherein the shallow trench isolation layer is formed from at least one material selected from the group consisting of silicon dioxide (SiO₂), silicon oxide (SiO), a nitride, an undoped polysilicon, and combinations thereof.

8. The semiconductor device of claim 1, wherein the plurality of fins in the fin array are formed from at least one of silicon, gallium arsenide, germanium, or a nano sheet stack.

9. The semiconductor device of claim 1, wherein the fin array is formed as part of a FinFET or a Nanosheet FET.

10. A method of forming a semiconductor device, comprising:
forming a fin array based, at least in part, on depositing a mask layer on a top surface of a substrate and patterning the mask layer and the substrate to form a plurality of fins and a plurality of trenches located therebetween;
forming a shallow trench isolation layer, wherein an upper portion of the plurality of fins is located above a top surface of the shallow trench isolation layer and a bottom portion of the plurality of fins is located below the top surface of the shallow trench isolation layer;
forming a liner on exposed surfaces of the plurality of fins, the mask layer located on top of the plurality of fins, and the shallow trench isolation layer; and
trimming the upper portion of edge fins in the fin array located above the top surface of the shallow trench isolation layer.

11. The method of claim 10, wherein forming the shallow trench isolation layer further includes:
depositing a shallow trench isolation material within the plurality of trenches and on the top surface of the substrate adjacent to the edge fins in the fin array; and
recessing a portion of the shallow trench isolation material to expose the upper portion of the plurality of fins located above the top surface of the shallow trench isolation layer.

12. The method of claim 10, wherein trimming the upper portion of the edge fins further includes:
removing respective portions of an exposed outer sidewall of the edge fins in the fin array located above the shallow trench isolation layer via an angled reactive ion etch that is selective to the plurality of fins over the shallow trench isolation layer and the liner.

13. The method of claim 12, wherein the angled reactive ion etch is terminated when a smallest lateral width of the upper portion of the edge fins in the fin array located above the shallow trench isolation layer is substantially similar to a smallest lateral width of the upper portion of the one or more inner fins in the fin array located above the shallow trench isolation layer; and
a largest lateral width of the upper portion of the edge fins in the fin array located above the shallow trench isolation layer is substantially similar to a largest lateral width of the upper portion of the one or more inner fins in the fin array located above the shallow trench isolation layer.

14. The method of claim 10, further comprising:
responsive to trimming the upper portion of the edge fins in the fin array located above the top surface of the shallow trench isolation layer, removing the mask layer and the liner from the semiconductor device.

15. The method of claim 10, wherein the plurality of fins in the fin array are formed from at least one of silicon, gallium arsenide, germanium, or a nanosheet stack.

16. The method of claim 10, wherein the shallow trench isolation layer is formed from at least one material selected from the group consisting of silicon dioxide (SiO₂), silicon oxide (SiO), a nitride, an undoped polysilicon, and combinations thereof.

17. The method of claim 10, wherein the fin array is formed as part of a FinFET or a Nanosheet FET.
